(19) United States
(12) Patent Application Publication
(10) Pub. No.: US 2016/0308171 A1
(43) Pub. Date: Oct. 20, 2016

(54) DEPOSITION SOURCE FOR ORGANIC LIGHT-EMITTING DISPLAY APPARATUS

(71) Applicant: Samsung Display Co., Ltd., Yongin-si (KR)

(72) Inventor: Youjong LEE, Yongin-si (KR)

(21) Appl. No.: 14/923,869

(22) Filed: Oct. 27, 2015

(30) Foreign Application Priority Data
Apr. 15, 2015 (KR) 10-2015-0053143

(51) Int. Cl. H01L 51/56

(52) U.S. Cl. CPC H01L 51/56

(57) ABSTRACT

A deposition source for an organic light-emitting display apparatus including a deposition housing. The deposition housing includes a nozzle configured to spraying a deposition material, evaporation spaces configured to evaporate the deposition material, and a separation wall configured to partition the evaporation spaces and form a transfer path of the deposition material. The deposition source also includes a storage container disposed at a side of the deposition housing, the storage container configured to store the deposition material, a heating body disposed between the deposition housing and the storage container configured to heat at least a portion of the deposition material, an evaporator disposed in the deposition housing for evaporating the deposition material heated by the heating body, and a heater provided on an outer surface of the deposition housing.

### CROSS-REFERENCE TO RELATED APPLICATION

This application claims priority from and the benefit of Korean Patent Application No. 10-2015-0053143, filed on Apr. 15, 2015, which is hereby incorporated by reference for all purposes as if fully set forth herein.

### BACKGROUND

1. Field

Exemplary embodiments relate to a deposition source for an organic light-emitting display apparatus.

2. Discussion of the Background

In general, an organic light-emitting display apparatus including a thin film transistor (TFT) may be used in a mobile device (i.e., a smartphone, a tablet personal computer (PC), a laptop, a digital camera, a camcorder, or a portable information terminal) or another electric apparatus such as a desktop computer, a television, or an outdoor billboard.

An organic light-emitting display apparatus may include an anode, a cathode, and an organic emission layer disposed between the anode and the cathode. A thin film such as an organic emission layer may be formed by a deposition process.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide a deposition source for an organic light-emitting display apparatus.

Additional aspects will be set forth in the detailed description which follows, and, in part, will be apparent from the disclosure, or may be learned by practice of the inventive concept.

An exemplary embodiment discloses a deposition source for an organic light-emitting display apparatus including a deposition housing. The deposition housing includes a nozzle configured to spraying a deposition material, evaporation spaces configured to evaporate the deposition material, and a separation wall configured to partition the evaporation spaces and form a transfer path of the deposition material. The deposition source also includes a storage container disposed at a side of the deposition housing, the storage container configured to store the deposition material, a heating body disposed between the deposition housing and the storage container configured to heat at least a portion of the deposition material, an evaporator disposed in the deposition housing for evaporating the deposition material heated by the heating body, and a heater provided on an outer surface of the deposition housing.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a schematic cross-sectional view of a deposition source for an organic light-emitting display apparatus according to an exemplary embodiment.

FIG. 2 is an exploded perspective view of a heater of FIG. 1.

FIG. 3 is a schematic block diagram illustrating deposition of a thin film on a substrate by using the deposition source of FIG. 1.

FIG. 4 is a perspective view of a deposition source for an organic light-emitting display apparatus according to an exemplary embodiment.

FIG. 5 is a diagram illustrating the inside of the deposition source of FIG. 4.

FIG. 6 is a perspective view of an organic light-emitting display apparatus in an unfolded state according to an exemplary embodiment.

FIG. 7 is a perspective view of an organic light-emitting display apparatus of FIG. 6 in a curved state.

FIG. 8 is a cross-sectional view of a sub-pixel in an organic light-emitting display apparatus according to an exemplary embodiment.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

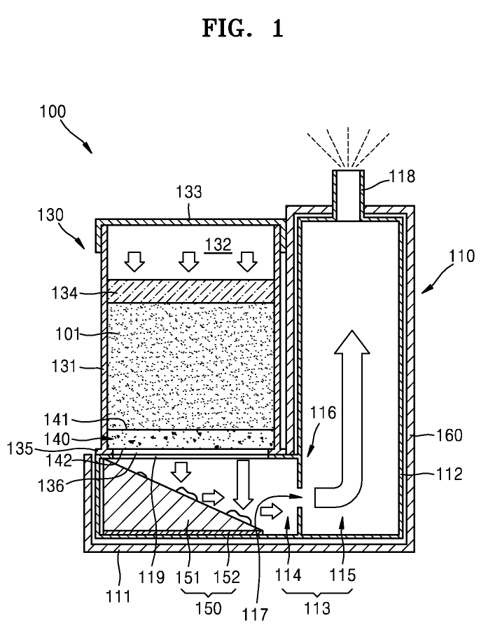

FIG. 1 is a diagram of a deposition source 100 for an organic light-emitting display apparatus according to an exemplary embodiment.

Referring to FIG. 1, the deposition source 100 may include a deposition housing 110 having a nozzle 118, a storage container 130 provided at a side of the deposition housing 110 for storing a deposition material 101, a heating body 140 provided between the deposition housing 110 and the storage container 130, an evaporator 150 provided in the deposition housing 110, and a heater 160 provided on an outer surface of the deposition housing 110.

The deposition housing 110 may include a first deposition housing 111 extending in a horizontal direction, and a second deposition housing 112 connected to an end portion of the first deposition housing 111 and extending in a vertical direction. The first deposition housing 111 may be formed integrally with the second deposition housing 112. The deposition housing 110 may include metal or ceramic.

In an exemplary embodiment, the deposition housing 110 is not limited to a particular shape provided that there is an evaporation space for evaporating the deposition material 101 in the deposition housing 110. The deposition material 101 may be a raw material for forming an emissive layer included in an organic light-emitting diode. But the deposition material 101 is not limited to a raw material for forming an emissive layer included in an organic light-emitting diode.

An evaporation space 113 for evaporating the deposition material 101 may be disposed or otherwise formed in the deposition housing 110. More specifically, the first deposition housing 111 may include a first evaporation space 114 and the second deposition housing 112 may include a second evaporation space 115. The first and second evaporation spaces 114 and 115 may be connected to each other.

A separation wall 116 may be provided between the first evaporation space 114 and the second evaporation space 115. The separation wall 116 may provide a moving passage through which the deposition material 101 moves in the evaporation space 113.

The separation wall 116 may be a metal plate. The separation wall 116 may separate the first evaporation space 114 from the second evaporation space 115. The separation wall 116 may be integrally formed in the deposition housing 110 with the deposition housing 110. In an exemplary embodiment, the separation wall 116 may be separately manufactured and then coupled to the deposition housing 110.

The separation wall 116 may include an opening 117. The opening 117 may be disposed or otherwise formed in a center of the separation wall 116. The opening 117 may be a transfer path of the deposition material 101 that moves from the first evaporation space 114 to the second evaporation space 115. In an exemplary embodiment, the opening 117 may have a size that varies depending on a kind of the deposition material 101 to be deposited.

In an exemplary embodiment, the separation wall 116 may be connected to an additional driver (not shown) for varying the size of the opening 117. For example, the size of the opening 117 may be reduced or increased in order to adjust an evaporation amount of the deposition material 101.

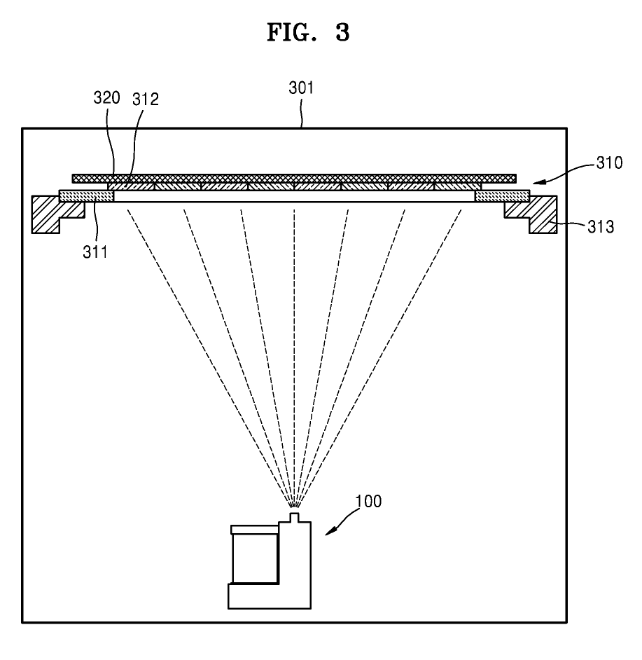

The nozzle 118 (i.e., an exit for spraying the evaporating deposition material 101) may be disposed or otherwise formed on an upper end of the second deposition housing 112. The nozzle 118 may be connected to the second evaporation space 115. Although only one nozzle 118 is shown in FIG. 1, multiple nozzles 118 may be provided and separated from each other along a direction (a substantially horizontal direction) of the second deposition housing 112. As shown in FIGS. 1 and 3, the deposition material 101 discharged through the nozzle 118 (or nozzles) may be sprayed toward a substrate 320.

A first deposition housing opening 119 may be disposed or otherwise formed in an upper portion of the first deposition housing 111. The first deposition housing opening 119 may be a single opening. In addition, the first deposition housing opening 119 may be a circular opening. In an exemplary embodiment, the first deposition housing opening 119 may be multiple openings that are separate from each other.

The first deposition housing opening 119 may be disposed or otherwise formed in first deposition housing 111 and the storage container 130 may be disposed or otherwise formed on the first deposition housing 111. The storage container 130 may have a cylindrical shape. The storage container 130 may include a storage housing 131 having an internal space 132 for storing the deposition material 101. A cover 133 may cover an entrance of the storage housing 131.

A storage housing opening 136 may be disposed or otherwise formed in a bottom 135 of the storage housing 131. The storage housing opening 136 may be disposed or otherwise formed by opening at least a part of the bottom 135 of the storage housing 131. The storage housing opening 136 may be disposed or otherwise formed to correspond to the first deposition housing opening 119. For example, the storage housing opening 136 may have the opening area as the first deposition housing opening 119 and may be aligned with the first deposition housing opening 119. Since the storage housing opening 136 and the first deposition housing opening 119 are disposed or otherwise formed, the internal space 132 of the storage housing 131 and the first evaporation space 114 of the first deposition housing 111 may be connected to each other.

The heating body 140 may be provided between the first deposition housing 111 and the storage container 130. More specifically, the heating body 140 may be mounted on the bottom 135 of the storage housing 131. The heating body 140 may completely cover the storage housing opening 136.

The heating body 140 may be variously mounted on the bottom 135 of the storage housing 131. For example, a flange may be disposed or otherwise formed on the bottom 135 of the storage housing 131, and the heating body 140 may be mounted on the flange. In an alternate example, the heating body 140 may be located on the bottom 135 of the storage housing 131 and then coupled to the bottom 135 by using a bolt. However, the coupling structure is not limited to the examples listed. The coupling structure may include any structure variation so long as the heating body 140 completely covers the storage housing opening 136.

The deposition material 101 may be filled on the heating body 140. The deposition material 101 may be a raw material of the material that is to be deposited on the substrate 320 (i.e., a deposition target). The deposition material 101 may evaporate directly without being liquefied, or may evaporate after being liquefied when the deposition material 101 is heated.

A compression plate 134 for compressing the deposition material 101 may be provided in the storage housing 131. In an exemplary embodiment, the compression plate 134 may be a disc type corresponding to the shape of the storage housing 131.

The compression plate 134 may compress the deposition material 101 filled in the storage housing 131 with a predetermined pressure. Accordingly, the deposition material 101 and the heating body 140 may contact each other with a predetermined pressure applied to the deposition material 101 by the compression plate 134.

Moreover, the compression plate 134 may prevent some of the deposition material 101 from agglomerating in advance, when the deposition material 101 evaporates. In an exemplary embodiment, the compression plate 134 may be connected to a compression unit (not shown) to adjust the pressure.

A first surface 141 of the heating body 140 may directly contact the deposition material 101. A second surface 142 of the heating body 140, which is opposite to the first surface 141, may be on the first deposition housing 111 and may be connected to the first evaporation space 114. The second surface 142 of the heating body 140 may be coupled to the first deposition housing 111 so as to cover the first deposition housing opening 119.

The heating body 140 may be a structure that may partially heat at least a portion of the deposition material 101 (i.e., a surface of the deposition material 101 contacting the first surface 141 of the heating body 140). The heating body 140 may include a porous plate.

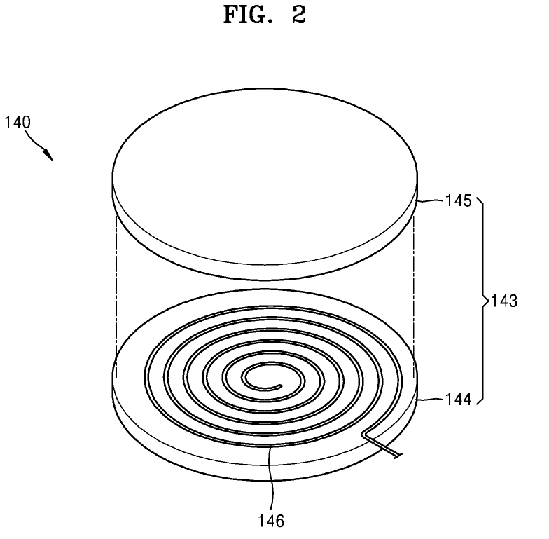

Referring to FIG. 2, the heating body 140 may include at least one porous heating plate 143 and a heating element 146 provided on the porous heating plate 143 to heat the porous heating plate 143.

The porous heating plate 143 may include a first heating plate 144 and a second heating plate 145 coupled onto the first heating plate 144. The size and shape of the first heating plate 144 may be substantially the same as the second heating plate 145. In an exemplary embodiment, the first heating plate 144 and the second heating plate 145 are formed as discs corresponding to the shape of the storage housing 131.

The first heating plate 144 and the second heating plate 145 may be manufactured by using a porous material. In particular, the first and second heating plates 144 and 145 may be porous so that the deposition material heated by the heating body 140 may pass through the heating body 140 toward the first evaporation space 114 of the first deposition housing 111.

In an exemplary embodiment, the first and second heating plates 144 and 145 are formed of metal foam or graphite having porosity. The material for forming the first and second heating plates 144 and 145 is not limited to a particular material. Instead, any material having porosity may be used to form the first and second heating plates 144 and 145.

In an exemplary embodiment, the first and second heating plates 144 and 145 may be porous copper (Cu) discs. The first and second heating plates 144 and 145 may have a porosity of a degree that makes particles of the deposition material 101 not pass through the heating body 140 (i.e., a porosity of 90% or greater).

In an exemplary embodiment, the first heating plate 144 and the second heating plate 145 are formed of a material having an excellent thermal conductivity.

The heating element 146 may be disposed between the first heating plate 144 and the second heating plate 145. The heating element 146 may be disposed in a coil shape. The first heating plate 144 and the second heating plate 145 may be simultaneously heated by the heating element 146.

The heating body 140 may have any structure, provided that the deposition material 101 is heated by the heating body 140. For example, the porous heating body 140 may include an additional heating body so that a heating element contacts the additional heating body or an induction heating coil may be disposed under the porous heating body 140. In this example, the porous heating body 140 may have side surfaces that are heated. In an exemplary embodiment, the heating body 140 includes a single heating plate.

The heating body 140 may be heated to a temperature that is greater than or equal to an evaporation temperature or a melting temperature of the deposition material 101. Accordingly, the deposition material 101 contacting the heating body 140 may evaporate or melt depending on the deposition material 101.

More specifically, the deposition material 101 that directly evaporates without being liquefied may evaporate when the temperature of the heating body 140 is maintained at a temperature that is greater than or equal to the evaporation temperature of the deposition material 101. A temperature of the evaporator 150 and a temperature of the nozzle 118 may be also maintained to be greater than or equal to the evaporation temperature of the deposition material 101.

In an exemplary embodiment, the deposition material 101 may be liquefied when the temperature of the heating body 140 is maintained to be greater than or equal to the melting temperature of the deposition material 101. The temperature of the evaporator 150 and the nozzle 118 may be maintained to be greater than or equal to the evaporation temperature of the deposition material 101 such that the liquefied deposition material 101 evaporates when exposed to the heat from the evaporator 150 and the nozzle 118.

In an exemplary embodiment, the heating body 140 may control an evaporation amount or a melting amount of the deposition material 101 by controlling the temperature of the heating body 140, the evaporator 150, and the nozzle 118.

The evaporator 150 that evaporates the deposition material 101 heated by the heating body 140 may be provided in the deposition housing 110. The evaporator 150 may be located in the first evaporation space 114 where the deposition material 101 moves from the heating body 140 to the separation wall 116. In an exemplary embodiment, the evaporator 150 is provided under the heating body 140.

The evaporator 150 may include an evaporation plate 151 and a heating element 152 for heating the evaporation plate 151. The evaporation plate 151 may be provided at a location where the deposition material 101 of a liquid phase transferred from the heating body 140 may contact the evaporation plate 151. The evaporation plate 151 may be a metal plate having an excellent thermal conductivity. In an exemplary embodiment, the evaporation plate 151 has a triangular cross-section, but is not limited to such a structure. Instead, the evaporation plate 151 may have any structure provided that the deposition material 101 of the liquid phase may contact the evaporation plate 151.

The heating element 152 may be disposed between the evaporation plate 151 and the first deposition housing 111. The evaporation plate 151 may be heated by the heating element 152.

The deposition material 101 melted by the heating body 140 may evaporate on the evaporation plate 151 and proceed toward the separation wall 116. The evaporated deposition material 101 may be sprayed to the substrate 320 (i.e. a deposition target) through the nozzle 118.

In addition, the heater 160 may be provided on the outer surface of the deposition housing 110. The heater 160 may be disposed or otherwise formed on the entire outer surfaces of the first deposition housing 111 and the second deposition housing 112. However, the heater 160 may not be disposed or otherwise formed on regions of the deposition first deposition housing 11 and the second deposition housing 112 where the storage container 130 and the heating body 140 meet. The deposition housing 110 and the nozzle 118 may be simultaneously heated by the heater 160.

Operations of the deposition source 100 having the above structure will be described below with reference to FIG. 1, FIG. 2, and FIG. 3.

Referring to FIGS. 1 to 3, a chamber 301 is prepared. In an exemplary embodiment, the chamber 301 may be a vacuum chamber for forming an organic emission layer of the organic light-emitting display apparatus.

The deposition source 100 may be provided on a lower portion of the chamber 301.

A mask assembly 310 may be provided on an upper portion in the chamber 301. The mask assembly 310 may include a mask frame 311 and a mask 312 including at least one stick mask mounted on the mask frame 311. A deposition substrate 320 may be located on the mask 312. A holder 313 for holding the mask frame 311 may be further provided at edges of the mask frame 311.

The deposition material 101 may be sprayed from the deposition source 100 toward the substrate 320. The evaporating deposition material 101 may be deposited at a desired deposition area on the substrate 320 after passing through slits of the mask 312.

Spraying processes of the deposition material 101 from the deposition source 100 are as follows.

During the deposition processes, a predetermined amount electric power is applied to the heating body heating element 146, the evaporating heating element 152, and the outer surface heater 160 formed on the outer surface of the deposition housing 110. Therefore, the deposition housing 110, the nozzle 118, the heating body 140, and the evaporator 150 are simultaneously heated to a predetermined temperature.

When the heating plate 143 of the heating body 140 is heated, the surface of the deposition material 101 directly contacting the first surface 141 of the heating plate 143 is locally heated. The heated deposition material 101 may evaporate or melt depending on the melting point and boiling point of the particular deposition material 101.

The deposition material 101 that evaporates without being liquefied moves to the first evaporation space 114 of the first deposition housing 111 and passes through the opening 117 of the separation wall 116 toward the second evaporation space 115 of the second deposition housing 112. After that, the deposition material 101 is sprayed toward the substrate 320 through the nozzle 118.

Here, the temperature of the heating plate 143 has to be maintained to be greater than or equal to the evaporation temperature of the deposition material 101. Also, the temperatures of the evaporation plate 151 of the evaporator 150 and the nozzle 118 have to be maintained to be greater than or equal to the evaporation temperature of the deposition material 101.

The deposition material 101 that evaporates after being liquefied moves to the first evaporation space 114 of the first deposition housing 111. The deposition material 101 of the liquid phase may evaporate by the evaporation plate 151 in the first evaporation space 114 and then move to the second evaporation space 115 of the second deposition housing 112 after passing through the opening 117 of the separation wall 116. After that, the deposition material 101 is sprayed toward the substrate 320 through the nozzle 118.

Here, the temperature of the heating plate 143 is maintained to be greater than or equal to the melting temperature of the deposition material 101. However, the temperatures of the evaporation plate 151 of the evaporator 150 and the nozzle 118 have to be maintained to be greater than or equal to the evaporation temperature of the deposition material 101.

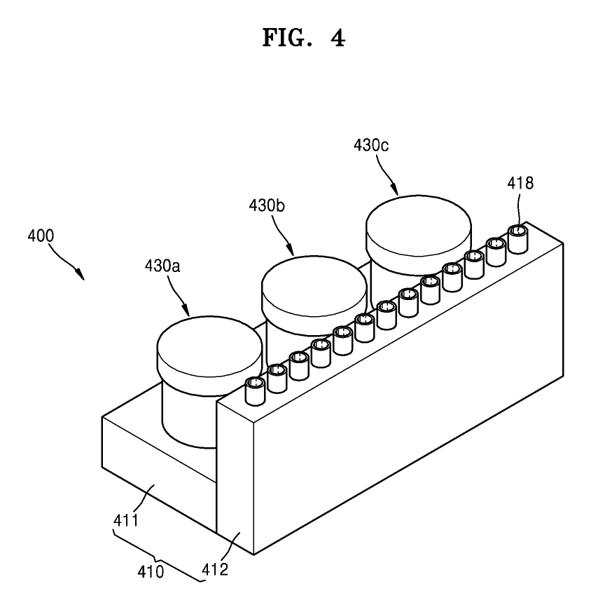

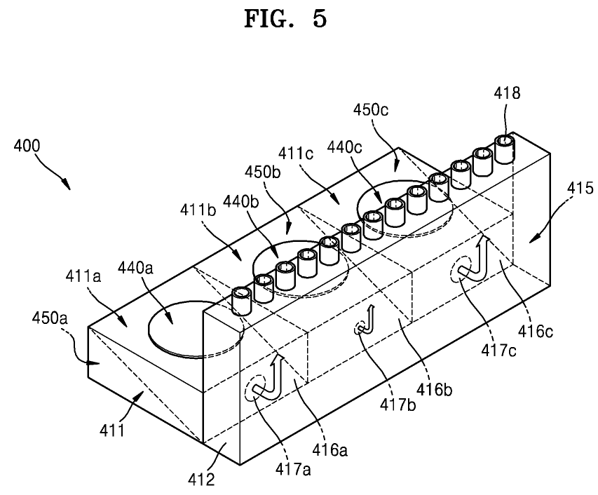

FIG. 4 is a perspective view of a deposition source 400 according to an exemplary embodiment. FIG. 5 is a diagram showing the inside of the deposition source 400 of FIG. 4.

The deposition source 400 of an exemplary embodiment includes a multiple deposition sources. The functions of various elements of deposition source 400 are substantially the same as the functions of the elements included in the deposition source 100 of FIG. 1. Thus, the detailed descriptions the substantially similar functions are omitted for brevity.

Referring to FIGS. 4 and 5, the deposition source 400 may include a deposition housing 410 including a multiple nozzles 418. The deposition housing 410 may include a first deposition housing 411 extending in a horizontal direction and a second deposition housing 412 connected to a side of the first deposition housing 411 and extending in a vertical direction.

Multiple first evaporation spaces 411a, 411b, and 411c that are independently separate from one another may be formed in the first deposition housing 411. In an exemplary embodiment, the first deposition housing 411 is divided into three first evaporation spaces 411 a, 411b, and 411c, but the number of first evaporation spaces 411a, 411b, and 411c may vary depending on the deposition material. The second deposition housing 412 may include a second evaporation space 415. The first evaporation spaces 41 la, 411b, and 411c and the second evaporation space 415 may be connected to each other.

Separation walls 416a, 416b, and 416c may be formed respectively between the separate first evaporation spaces 411 a, 411b, and 411 c and the second evaporation space 415. The separation walls 416a, 416b, and 416c respectively may include openings 417a, 417b, and 417c that form transfer paths of the deposition material 101 (see FIG. 1) that moves from the first evaporation spaces 411a, 411b, and 411c corresponding respectively to the separation walls 416a, 416b, and 416c and to the second evaporation space 415.

Storage containers 430a, 430b, and 430c may be provided on the first deposition housing 411. Heating bodies 440a, 440b, and 440c may be disposed respectively between the storage containers 430a, 430b, and 430c and the first deposition housing 411. The storage containers 430a, 430b, and 430c, the heating bodies 440a, 440b, and 440c, and the first deposition housing 411 may be connected to one another, and the deposition material 101 that is heated by the heating bodies 440a, 440b, and 440c may move to the first evaporation spaces 411a, 411b, and 411c that are separate from each other.

In an exemplary embodiment, the storage containers 430a, 430b, and 430c are coupled to a deposition material supply apparatus (not shown) provided outside the chamber 301 to supply a deposition material continuously.

Evaporators 450a, 450b, and 450c that evaporate the deposition material 101 heated by the heating bodies 440a, 440b, and 440c may be provided in the first deposition housing 411. The evaporators 450a, 450b, and 450c may be respectively formed in the first evaporation spaces 411a, 411b, and 411c that are separate from each other.

In an exemplary embodiment, the storage containers 430a, 430b, and 430c store different deposition materials 101. For example, deposition materials 101 may be used to form a blue emission layer of the organic emission layer. The deposition materials 101 may be respectively stored in the storage containers 430a, 430b, and 430c.

Evaporation amounts of the deposition materials 101 that are evaporated by the heating bodies 440a, 440b, and 440c or the evaporators 450a, 450b, and 450c may be adjusted by forming the openings 417a, 417b, and 417c with different diameters from each other in the separation walls 416a, 416b, and 416c.

In an exemplary embodiment, the deposition materials 101 pass through the separation walls 416a, 416b, and 416c having the openings 417a, 417b, and 417c of different sizes from the first evaporation spaces 411a, 411b, and 411c that are separate from each other. Then the deposition materials 101 move to the single second evaporation space 415 to be mixed. In an embodiment, a mixing ratio of the deposition materials 101 may be adjusted.

In an exemplary embodiment, the evaporation amounts of the deposition materials 101 may be adjusted by varying the areas of the heating bodies 440a, 440b, and 440c.

According to the deposition source 400 having the above-described structure, the amounts of the gases that are evaporated from the heating bodies 440a, 440b, and 440c or the evaporators 450a, 450b, and 450c may be adjusted by forming the openings 417a, 417b, and 417c in the separation walls 416a, 416b, and 416c with different diameters. The gases of the deposition materials 101 may be deposited on a substrate.

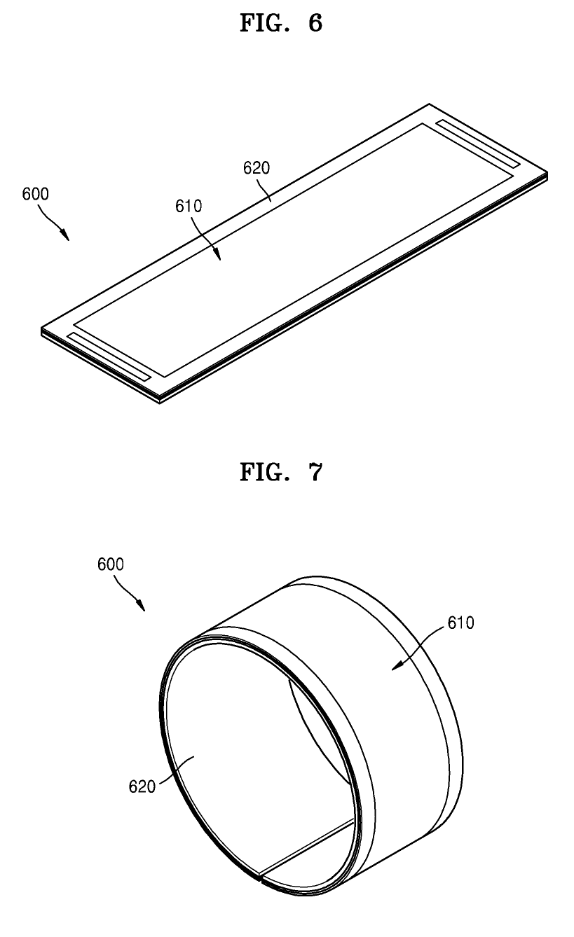

FIG. 6 is a perspective view of an organic light-emitting display apparatus 600 in a curved state with an organic emission layer formed on a substrate by using the deposition source 100 of FIG. 1. FIG. 7 is a perspective view of the organic light-emitting display apparatus 600 of FIG. 6 in a curved state.

Referring to FIGS. 6 and 7, the organic light-emitting display apparatus 600 may include a flexible display panel 610 for displaying images, and a flexible holder 620 coupled to the flexible display panel 610. The flexible display panel 610 may include various films such as a touch screen, a polarization plate, and a window cover, as well as a device for displaying the images. The flexible display apparatus 600 may display the images in various states (i.e., a flat state or a curved state).

In an exemplary embodiment, the organic light-emitting display apparatus 600 is a flexible apparatus, but may be applied to an organic light-emitting display apparatus that is rigid.

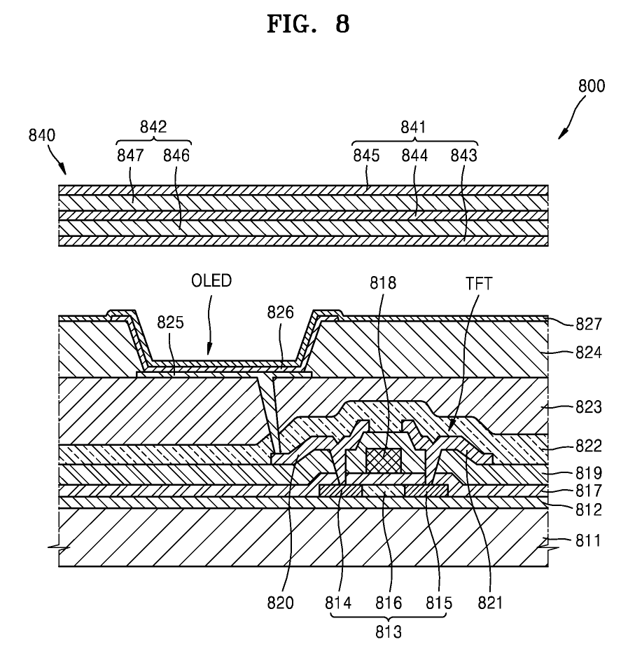

FIG. 8 is a cross-sectional view of a sub-pixel in an organic light-emitting display apparatus 800 where an organic emission layer is formed on a substrate by using the deposition source 100 of FIG. 1.

Referring to FIG. 8, the organic light-emitting display apparatus 800 may include a substrate 811 and an encapsulation 840 that is a thin film facing the substrate 811.

The substrate 811 may be at least one of glass substrate, a polymer substrate, and a flexible film substrate. The substrate 811 may be transparent, semi-transparent, or opaque.

A barrier layer 812 may be disposed or otherwise formed on the substrate 811. The barrier layer 812 may entirely cover an upper surface of the substrate 811. The barrier layer 812 may include at least one of an inorganic material or an organic material. The barrier layer 812 may be formed to have a single-layered or a multi-layered structure. The barrier layer 812 may prevent oxygen and moisture from infiltrating into the substrate 811 as well as create a plane surface on the upper surface of the substrate 811.

A thin film transistor TFT may be disposed or otherwise formed on the barrier layer 812. In an exemplary embodiment, the thin film transistor TFT is a top gate transistor, but is not limited to a top gate transistor. Instead, the thin film transistor TFT may have any suitable structure. For example, the thin film transistor may be a bottom gate transistor.

A semiconductor active layer 813 may be disposed or otherwise formed on the barrier layer 812.

The semiconductor active layer 813 may include a source region 814 and a drain region 815 that are formed by doping N type impurity ions or P type impurity ions. A channel region 816 (i.e., a non-doped region) may be disposed between the source region 814 and the drain region 815. The semiconductor active layer 813 may include at least one of an organic semiconductor and inorganic semiconductor. For example, the semiconductor active layer 813 may include amorphous silicon. In an exemplary embodiment, the semiconductor active layer 813 includes an oxide semiconductor.

A gate insulating layer 817 may be disposed or otherwise formed on the semiconductor active layer 813. The gate insulating layer 817 may include an inorganic layer. The gate insulating layer 817 may include a single-layered structure or a multi-layered structure.

A gate electrode 818 may be disposed or otherwise formed on the gate insulating layer 817. The gate electrode 818 may include a metal material having an excellent conductivity. The gate electrode 818 may include a single-layered structure or a multi-layered structure.

An interlayer insulating layer 819 may be disposed or otherwise formed on the gate electrode 818. The interlayer insulating layer 819 may include at least one of an inorganic layer and an organic layer.

A source electrode 820 and a drain electrode 821 may be disposed or otherwise formed on the interlayer insulating layer 819. More specifically, contact holes may be formed by partially removing the gate insulating layer 817 and the interlayer insulating layer 819, and the source electrode 820 may be electrically connected to the source region 814 and the drain electrode 821 may be electrically connected to the drain region 815 via the contact holes.

A passivation layer 822 may be disposed or otherwise formed on the source electrode 820 and the drain electrode 821. The passivation layer 822 may include at least one of an inorganic layer and an organic layer. A planarization layer 823 may be disposed or otherwise formed on the passivation layer 822. The planarization layer 823 may include an organic layer. In an exemplary embodiment, one of the passivation layer 822 and the planarization layer 823 is omitted.

The thin film transistor TFT may be electrically connected to an organic light-emitting diode OLED.

The organic light-emitting diode OLED may be disposed or otherwise formed on the planarization layer 823. The organic light-emitting diode OLED may include a first electrode 825, an intermediate layer 826, and a second electrode 827.

The first electrode 825 may function as an anode and may include any suitable conductive material. The first electrode 825 may be a transparent electrode, a reflective electrode, or some combination of a transparent electrode and reflective electrode. For example, when the first electrode 825 is used as the transparent electrode, the first electrode 825 may include a transparent conductive layer. When the first electrode 825 is used as the reflective electrode, the first electrode 825 may include a reflective layer and a transparent conductive layer formed on the reflective layer.

A pixel defining layer 824 may partially covers the planarization layer 823 and the first electrode 825. The pixel defining layer 824 may define an emission area in each of sub-pixels by surrounding edges of the first electrode 825. The first electrode 825 may be patterned in each of the sub-pixels.

The pixel defining layer 824 may include at least one of an organic layer and an inorganic layer. The pixel defining layer 824 may have a single-layered structure or a multi-layered structure.

The intermediate layer 826 may be disposed or otherwise formed on the first electrode 825 at a region that is exposed by etching a part of the pixel defining layer 824. The intermediate layer 826 may be formed by deposition processes. The intermediate layer 826 may be patterned by using the deposition source 100 of FIG. 1.

The intermediate layer 826 may include an organic emission layer. Alternately, the intermediate layer 826 includes the organic emission layer and at least one of a hole injection layer (HIL), a hole transport layer (HTL), an electron transport layer (EIL), and an electron injection layer (EIL). However, exemplary embodiments are not limited to an intermediate layer 826 including an organic emission layer or an organic emission layer and at least one of a hole injection layer (HIL), a hole transport layer (HTL), an electron transport layer (EIL), and an electron injection layer (EIL). Instead, the intermediate layer 826 may include the organic emission layer as well as any other functional layer.

The second electrode 827 may be disposed or otherwise formed on the intermediate layer 826.

The second electrode 827 may function as a cathode. The second electrode 827 may be a transparent electrode, a reflective electrode, or a combination of a transparent electrode and a reflective electrode. For example, when the second electrode 827 is used as the transparent electrode, the second electrode 827 may include a metal layer and a transparent conductive layer formed on the metal layer. When the second electrode 827 is used as the reflective layer, the second electrode 827 may include a metal layer.

In an exemplary embodiment, sub-pixels may be formed on the substrate 811, and each of the sub-pixels may emit red, green, blue, or white light. However, exemplary embodiments are not limited to sub-pixels emitting red, green, blue, or white light. Instead, sub-pixels may emit any light color.

In an exemplary embodiment, the intermediate layer 826 may be disposed or otherwise formed commonly on the first electrode 825 without regard to locations of the sub-pixels. The organic emission layer may be formed by vertically stacking layers, each including an emission material emitting red, green, or blue light, or by mixing emission materials emitting red, green, and blue light.

In an exemplary embodiment, any kind of color combination may be used provided that the white light may be emitted. A color converting layer or a color filter for converting the white light into a predetermined color may be further used.

The encapsulation 840 may be formed to protect the organic light-emitting diode OLED against external moisture or oxygen. In an exemplary embodiment, the encapsulation 840 may include a structure that stacks inorganic layers 841 and organic layers 842 alternately. For example, the inorganic layers 841 may include a first inorganic layer 843, a second inorganic layer 844, and a third inorganic layer 845. The organic layers 842 may include a first organic layer 846 and a second organic layer 847.

According to exemplary embodiments, the deposition source for the organic light-emitting display apparatus may reduce degradation of the deposition material with respect to the heat, and a deposition speed may be improved.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. A deposition source for an organic light-emitting display apparatus, the deposition source, comprising:
a deposition housing comprising:
a nozzle configured to spraying a deposition material;
evaporation spaces configured to evaporate the deposition material; and
a separation wall configured to partition the evaporation spaces and form a transfer path of the deposition material;
a storage container disposed at a side of the deposition housing, the storage container configured to store the deposition material;
a heating body disposed between the deposition housing and the storage container configured to heat at least a portion of the deposition material;
an evaporator disposed in the deposition housing for evaporating the deposition material heated by the heating body; and
a heater provided on an outer surface of the deposition housing.

2. The deposition source of claim 1, wherein the evaporation spaces comprise:
a first evaporation space connected to the heating body through a deposition housing opening formed in the deposition housing, and
a second evaporation space connected to the nozzle and connected to the first evaporation space.

3. The deposition source of claim 2, wherein the separation wall is a plate disposed between the first evaporation space and the second evaporation space, and the separation wall comprises an opening that is the transfer path of the deposition material moving from the first evaporation space to the second evaporation space.

4. The deposition source of claim 2, wherein the deposition housing comprises:
a first deposition housing extending in a first direction comprising the first evaporation space and the deposition housing opening that is connected to the heating body; and
a second deposition housing connected to an end of the first deposition housing, the second deposition housing extending in a second direction and comprising the second evaporation space.

5. The deposition source of claim 2, wherein the storage container comprises a storage housing having an internal space for storing the deposition material and a cover for covering an entrance of the storage housing, and a storage housing opening corresponding to the deposition housing opening is formed in a bottom of the storage housing and the heating body covers the storage housing opening.

6. The deposition source of claim 5, wherein a compression plate configured to compress the deposition material is disposed in the storage container.

7. The deposition source of claim 2, wherein a first surface of the heating body contacts the deposition material and a second surface of the heating body is coupled to the deposition housing, the second surface of the heating body is opposite the first surface of the heating body.

8. The deposition source of claim 7, wherein the heating body comprises a porous plate.

9. The deposition source of claim 7, wherein the heating body comprises:
at least one porous heating plate; and
a heating element disposed on the at least one porous heating plate and configured to heat the at least one porous heating plate.

10. The deposition source of claim 9, wherein the at least one porous heating plate comprises:
a first heating plate; and
a second heating plate,
wherein the heating element is disposed between the first heating plate and the second heating plate.

11. The deposition source of claim 7, wherein the heating body is heated to a temperature that is greater than or equal to at least one of an evaporation temperature and a melting temperature of the deposition material.

12. The deposition source of claim 11, wherein the deposition material that evaporates without being liquefied is evaporated by maintaining a temperature of the heating body, a temperature of the evaporator, and a temperature of the nozzle to be greater than or equal to an evaporation temperature of the deposition material.

13. The deposition source of claim 11, wherein the deposition material that evaporates after being liquefied is evaporated by maintaining the temperature of the heating body to be greater than or equal to the melting temperature of the deposition material and maintaining the temperature of the evaporator and the temperature of the nozzle to be greater than or equal to the evaporation temperature of the deposition material.

14. The deposition source of claim 7, wherein at least one of an evaporation amount and a melting amount of the deposition material is controlled by controlling the temperature of the heating body.

15. The deposition source of claim 1, wherein the evaporator is located in the evaporation spaces.

16. The deposition source of claim 15, wherein the evaporator comprises:
an evaporation plate; and
a heating element configured to heat the evaporation plate.

17. The deposition source of claim 15, wherein the deposition material melted by the heating body is evaporated by the evaporator and transferred to the separation wall.

18. The deposition source of claim 1, wherein the deposition housing comprises first evaporation spaces that are independently separate from each other, and a second evaporation space, wherein separation walls are disposed respectively between the first evaporation spaces and the second evaporation space,
storage containers corresponding to the first evaporation spaces are disposed at a side of the deposition housing,
heating bodies are disposed respectively between the deposition housing and the storage containers, and
evaporators corresponding to the heating bodies are disposed in the deposition housing.

19. The deposition source of claim 18, wherein the second evaporation space is commonly connected to the first evaporation spaces.

20. The deposition source of claim 19, wherein the separation walls have openings of different sizes from each other to adjust a mixture ratio of the deposition material moving from the first evaporation spaces to the second evaporation space.
